(19) United States
(12) Patent Application Publication
(10) Pub. No.: US 2006/0029745 A1
(43) Pub. Date: Feb. 9, 2006

(54) High throughput ILD fill process for high aspect ratio gap fill

(76) Inventor: Gurtej S. Sandhu, Boise, ID (US)

Correspondence Address: Michael G. Fletcher;Fletcher, Yoder & Van Someren, P.O. Box 692289, Houston, TX, 77269-2289, US

(21) Appl. No.: 10/470,618

(22) Filed: Jan. 2, 2003

Related U.S. Application Data
(63) Continuation of application No. 09/754,440, filed on Jan. 4, 2001, now abandoned.
Application No. 09/754,440 is a continuation of application No. 08/813,135, filed on Mar. 7, 1997, now abandoned.
Application No. 08/813,135 is a continuation of application No. 08/472,329, filed on Jun. 7, 1995, now abandoned.

(51) Int. Cl. H05H 1/24; B44C 1/22; C23C 16/00

(52) U.S. Cl. 427/569; 216/37; 118/715

(57) ABSTRACT

A method for filling gaps in high aspect ratio patterned features on an integrated circuit using plasma CVD processes. A plasma is generated by an inert gas and process gases including silicon and oxygen components. The plasma causes the product gases to react and deposit onto the substrate and concurrently etch the deposited film. During an initial stage, the net deposition rate is kept low to improve filling of the high aspect ratio features, while during one or more later stages the net deposition rate is increased to provide a more conformal film at a higher throughput.

### BACKGROUND OF THE INVENTION

1. Field of the Invention

The present invention relates, in general, to chemical vapor deposition (CVD) apparatus and processes and, more particularly, to a high throughput method and apparatus for filling gaps and vias for interlayer dielectric (ILD) films in multi-layer metal (MLM) structures.

2. Statement of the Problem

Integrated circuit technology has advanced through continuing improvements in photolithographic processing so that smaller and smaller features can be patterned onto the surface of a substrate spaces or gaps exist between these patterned features. Integrated circuit surfaces also contain trench or via structures protruding down into the surface. The lateral dimension of such structures is hereafter referred to as the width of the gap, trench or via; the vertical dimension of such structures is referred to as the depth. The aspect ratio is the ratio of depth to width.

The smaller features, with smaller spaces between features, result in high aspect ratio gaps, trenches and vias. These high aspect ratio structures must be filled with an appropriate material before continued processing. This problem is acute in the case of multi-layer metal (MLM) designs where dielectric must be deposited after each metal layer is formed and patterned before a subsequent metal layer can be formed and patterned.

When a deposited film is used to completely fill the high aspect ratio structure three different results can emerge. In one case, the deposited material fills the trench without leaving a seam or void. In a second case, a seam arises from the point where the sidewall layers merge during deposition. In a third case, a void arises if the deposition produces re-entrant profiles at earlier stages of the filling process. The first creates the highest reliability integrated circuits. The seams and voids are undesirable, since chemicals or materials may be present in the seam or void to corrode or degrade the structure. Moreover, voids are, rarely hermetically sealed, so subsequent exposure to chemicals or materials deposition can alter the material structure substantially.

Deposition onto trench and via structures is commonly practiced at several stages in the fabrication of semiconductor devices and interconnections. Most often the objective is to provide rather highly conformal films or void-free (and preferably seam-free) filling. Low pressure chemical vapor deposition (LPCVD) and plasma enhanced chemical vapor deposition (PECVD) are widely used to provide conformal deposition of thin films over three dimensional features. Physical vapor deposition techniques (evaporation, sputter-deposition) are typically limited to low aspect ratio structures. LPCVD processes offer better conformality and filling properties.

A number of chemical vapor deposited (CVD) films are currently used at various steps of integrated circuit manufacturing processes. Typically, sidewall coverage is not uniform along the height of a trench or via. A tapered shape has thicker sidewall coverage toward the bottom of the sidewall than toward the top, while the situation is reversed for a re-entrant shape Generally speaking the tapered shape is more desirable than the re-entrant, because the overhang of deposited material near the top of the trench shadows the region below, and the consequences of subsequent deposition can be ill-defined.

CVD processes operate by confining one or more semiconductor wafers in a chamber. The chamber is filled with process gases comprising one or more reactant species. Energy is supplied within the chamber and particularly to the reactant species near the wafer surface. The energy activates the process gases to deposit from the reactant species a film onto the heated substrate. Such chemical vapor deposition of a solid onto a surface involves a heterogeneous surface reaction of the gaseous species that adsorb onto the surface. The rate of film growth and the quality of the film depend on the wafer surface temperature and on the gas species available.

More recently, low temperature plasma-enhanced deposition and etching techniques are used to form diverse materials, including metals such as aluminum and tungsten, dielectric films such as silicon nitride and silicon dioxide and semiconductor films such as silicon. The plasma used in the plasma enhanced chemical vapor deposition process (PECVD) is a low pressure plasma that is developed in an RF field. The RF plasma results in a very high electron temperature making possible the deposition of dense, good quality films at lower temperatures and faster deposition rates than are typically possible using purely thermally activated CVD processes.

Current CVD processes have important limitations. With higher integration levels or higher performance structures, higher aspect ratios are required, stretching the ability of known CVD processes. Re-entrant profiles, seams, and voids all endanger the manufacturability of the semiconductor product due to yield and reliability problems. Where higher growth temperatures improve conformality or profiles, other properties of the 3-D structure may be degraded (e.g., abrupt doping profiles due to diffusion). Alternatively, lower reaction probabilities (“reactive sticking coefficient”) for well-chosen CVD chemistries can yield higher conformality, but throughput is degraded, making the approach less competitive.

Also, conformality is improved by including film etching by physical (i.e. sputtering) or chemical (HCl) etchants in the reactor during the deposition. Simultaneous etching/deposit, however, provides low net deposition rates. Thus, conventional CVD processes may not be capable of efficiently providing the filling characteristics needed for next-generation technologies.

U.S. Pat. No. 5,182,221 issued to Sato on Jan. 26, 1993 describes a bias ECR-CVD process in which etching and deposition are simultaneously performed. In one embodiment, the Sato deposition process is performed in a single step with carefully controlled conditions to provide a ratio of vertical to horizontal deposition rates that will fill high aspect ratio trenches. In another embodiment, the Sato process is performed in multiple steps by changing the reactant species between the steps. This allows control of the deposited film topography, but sacrifices control over film composition. The Sato processes afford control at reduced deposition rates.

Step coverage and filling of high aspect ratio gaps with CVD films is a continuing problem in the IC manufacturing industry. Decreasing costs for most IC products forces increasingly efficient production and higher throughput at film deposition processes. What is needed is a method and apparatus for highly conformal CVD deposition with high throughput.

3. Solution to the Problem

The present invention solves the above problems by providing a high throughput CVD process offering controlled deposited layer thickness over high aspect ratio three-dimensional patterned features. The present invention provides the ability to control how the thickness of the deposited layer varies along bottom, sidewall, and top surfaces of high aspect ratio features patterned on an integrated circuit. The invention permits controlled shaping of thin film layers including, for example, (1) tapered rather than re-entrant shapes (i.e., thicker at the bottom rather than at the top), (2) enhanced sidewall and/or bottom coverage of trench structures, (3) voidless, seamless filling even at high aspect ratio with improved deposition rate for high throughput and low cost.

### SUMMARY OF THE INVENTION

Briefly stated, the present invention involves a method for making an integrated circuit including steps of forming a pattern defining a gap on a surface of a substrate. The substrate is placed in a plasma reactor. A plasma is generated of process gases including silicon and oxygen components. A bias supply provides a controllable, variable bias between the substrate and the plasma. The plasma causes the product gases to react and deposit onto the substrate and concurrently etch the deposited film. The bias level is varied to continuously control net deposition rate and topography of the deposited film. During an initial stage, the net deposition rate is kept low to improve filling of the high aspect ratio features, while during one or more later stages the net deposition rate is increased to provide a more conformal film at a higher throughput.

### BRIEF DESCRIPTION OF THE DRAWING

FIG. 1 illustrates a cross-section view of a simplified chemical vapor deposition reactor in accordance with the present invention; and

FIG. 2a-FIG. 2d illustrate a patterned semiconductor substrate at various stages of processing using the method in accordance the present invention.

### DETAILED DESCRIPTION OF THE DRAWING

1. Overview.

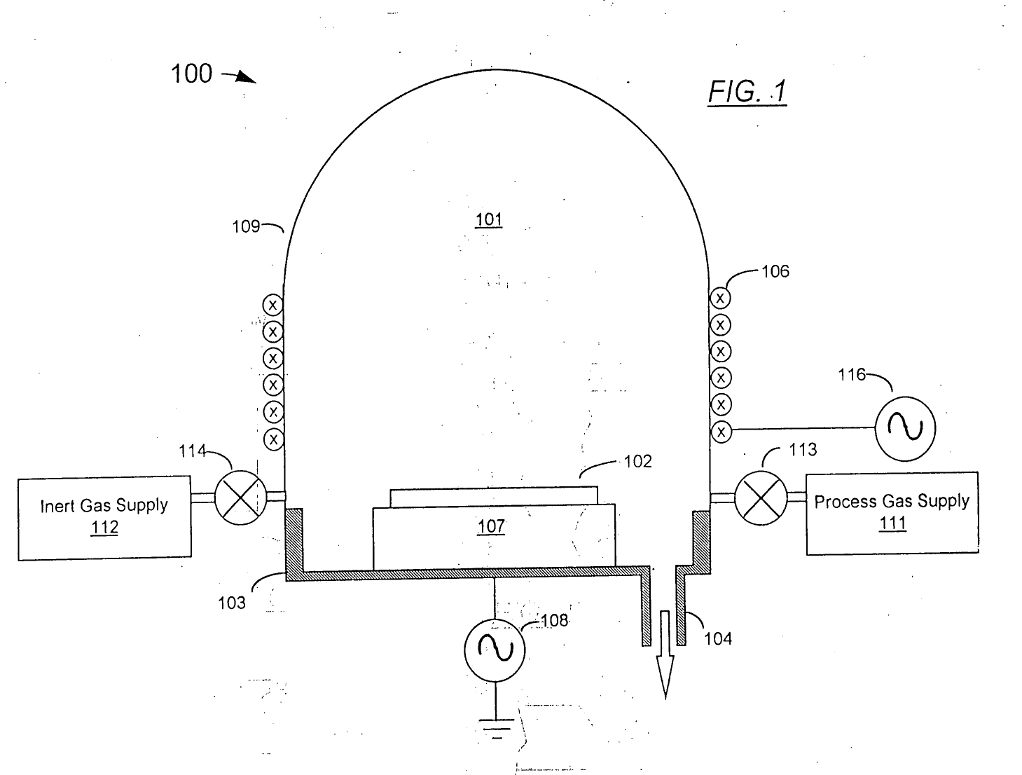

The present invention relates to a chemical vapor deposition (CVD) reactor 100 shown in FIG. 1 and a method for depositing CVD films. CVD reactor 100 is preferably configured as a high density plasma CVD reactor, although the teachings of the present invention can be modified to accommodate other CVD reactor configurations. Chamber 101 is a pressure sealed compartment for mounting a wafer 102 on susceptor 107. Chamber 101 includes a base 103 sealed by an enclosure 109. Base 103 is typically manufactured from aluminum. Enclosure 109 may comprise aluminum or a dielectric material depending on the type of system used to supply energy to CVD reactor 101. Base 103 and enclosure 109 are designed to contain a low pressure environment around wafer 102 as well as to contain process gases, exhaust gases, and plasma energy within chamber 101.

Process gases supplied to wafer 102 include a reactant species from process gas supply 111. The quantity of process gas supplied is regulated by flow controller 113. In a particular example, the reactant species include a silicon species and an oxygen species that can react to deposit a silicon dioxide film. Examples of silicon species include:
silane (SiH₄),
disilane (Si₂H₄),
tetraethyloxysilane (TEOS),
diacetoxditertiarybutoxysilate (DADBS),
diethylsilane (DES), and
tetramethylcyclotetrasilane (DES).

An etchant gas is also supplied to reactor 100. In a preferred embodiment, the etchant comprises inert gas from inert gas supply 112 such as argon that serves both as a carrier for the reactant species and to allow sputter etching within reactor 100. Alternatively, chemical etchants such as CF₄, CHF₃, NF₃ can be included at controlled rates to provide etching. Flourinated hydrocarbons can also result in deposition of fluorine doped SiO₂ which is desirable due to low dielectric constant.

In accordance with an embodiment of the present invention, the flow rate of etchant species provided by inlet gas manifold 103 is controllable by flow controller 114 so that it can be increased or reduced during the deposition process. Chamber 101 also incorporates a pumping system (not shown) for exhausting spent gases from chamber 101 through exhaust port 104.

CVD reactor 100 includes means for supplying energy to the reactant species in the process gases on the surface of the wafer 102. The supplied energy causes the reactant species to react or decompose and deposit a thin film onto an upper surface of wafer 102. Common means for supplying the energy include thermal energy supplied by heat lamps (not shown). Alternatively, susceptor 107 can be heated by heat lamps 106 and wafer 102 heated by conduction from susceptor 107.

In the preferred embodiment, reaction energy is supplied by creating an inductively coupled plasma within reactor 100. As shown in FIG. 1, RF generator 118 is coupled to induction coils 106 surrounding enclosure 101. When energized, inductive coils 106 create a magnetic field having a flux density in the range of 800-1000 Gauss, although a wide range of flux densities are possible. Alternate and equivalent CVD reactor designs are well known.

AC generator 108 creates an RF bias field between the plasma and substrate 102. This bias field serves to control the energy with which ionized species from the plasma within chamber 101 impact wafer 102. In the preferred embodiment, AC generator 108 is controllable so that a bias potential appearing on wafer 102 can be controlled throughout the deposition process independently of any self bias created by RF supply 118. Alternatively, AC generator 108 may be replaced by a magnetic field bias that serves essentially an equivalent purpose to the electric field bias illustrated as the preferred embodiment.

CVD reactor 100 is illustrated as a single wafer reactor, but it should be understood that the present invention is applicable to batch reactors of conventional designs. The preferred embodiment includes plasma reactors as these allow lower temperature film deposition and are preferable in the semiconductor industry. However, some reactant species in the process gases may deposit at low temperatures using only thermal energy or other energy source well known in the industry. Hence, the present invention encompasses reactor designs using energy sources including either thermal heating, inductively coupled RF plasma, capacitively coupled RF plasma, or the like.

Although the preferred embodiment is described in terms of a SiH₄+O₂ deposition, the teachings of the present invention are applicable to any reagent gas. These and other variations of the specific embodiments described herein are considered equivalent to the claimed invention.

2. Method of Operation.

Prior art CVD processes are used to provide a high quality low temperature thin film on a substrate. CVD processes are preferred, as set out hereinbefore, because of their ability to conformally deposit onto complex three-dimensional structures formed on an integrated circuit surface. Prior art systems typically deposit a CVD thin film in a single step using a single, known gas chemistry and plasma conditions. The single step deposition offers the advantage of consistency and simplicity.

The method of the present invention involves concurrent etching and deposition to coat high aspect ratio devices. In order to coat high aspect ratio structures, the deposition rate is reduced by including an etching means (i.e., sputtering or chemical etching) during the deposition process. In accordance with the present invention, varying substrate bias, power, reagent gas partial pressure, and inert gas partial pressure the deposition rate and conformality can be varied significantly.

In accordance with the present invention, the etch rate during the deposition is varied so as to increase the net deposition rate as the high aspect ratio gaps are filled. As the gaps are filled during an initial stage, deposition rate at the base of gaps is much greater than the deposition rate on the sidewalls. This is a known feature of concurrent etch/deposition processes. In accordance with the present invention, as the gap fills, the aspect ratio is reduced. The present invention takes advantage of this occurrence by reducing the etch rate, thereby increasing the net deposition rate when the aspect ratio is at a point where increased conformality can be tolerated.

The effect of the present invention is to increase the average deposition rate for the entire process to a level approaching that for purely conformal coatings. Hence, the method in accordance with the present invention provides the advantages of concurrent etch/deposit processes, while achieving the high deposition rate of conventional conformal deposition processes.

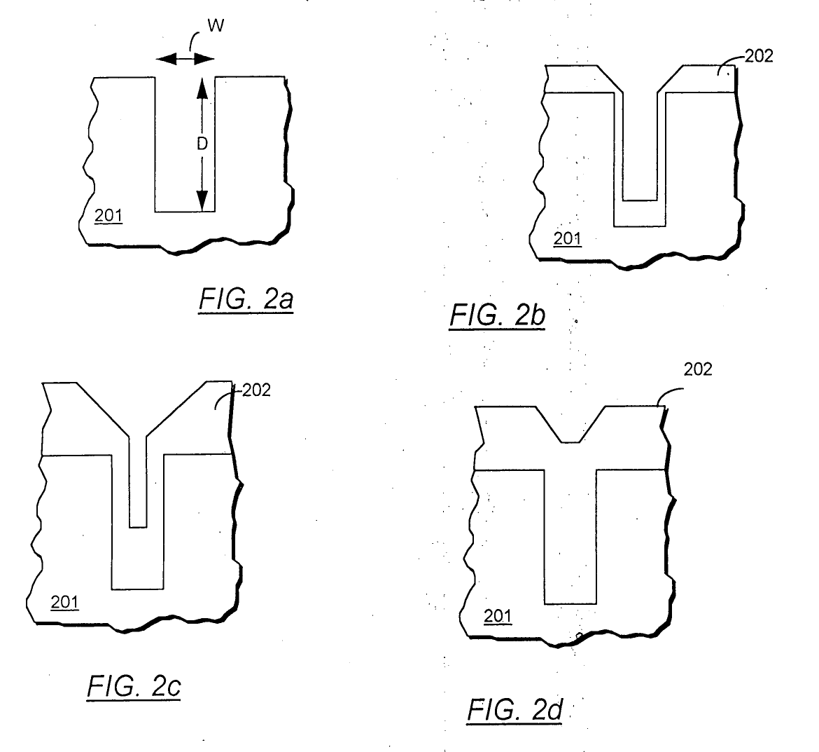

In accordance with the present invention, a substrate is processed through conventional integrated circuit steps to form devices and/or device structures into semiconductor wafer 102 (shown in FIG. 1). An upper surface 201, shown in FIG. 2a-FIG. 2d, is formed and patterned to have recessed gaps. Each of the gaps has a width (W) and a depth (D). An aspect ratio is the ratio of depth to width. FIG. 2b-2d set out various stages in accordance with the method of the present invention. At an initial stage shown in FIG. 2a, interlayer dielectric 202 is formed using concurrent etch and deposit of silicon dioxide in a plasma reactor. In the preferred embodiment, the concurrent etch is performed by sputter etching using argon in the plasma.

As shown in FIG. 2b, the concurrent deposit etch results in a higher growth rate at the base of the gap as compared to the sidewall surfaces. An angled profile at the upper portion of trench or via is characteristic of the concurrent etch/deposit process. This initial deposit cycle is continued until the gap has filled to a preselected level as shown in FIG. 2c. Although the interlayer dielectric 202 continues to deposit on sidewalls as shown in FIG. 2c, it deposits faster at the base thereby preventing seams and voids. However, the deposition process illustrated in FIGS. 2b and 2c is relatively slow due to the high etch back rate.

In accordance with the present invention, when the interlayer dielectric has filled to the preselected level shown in FIG. 2c, the etch rate is reduced (and/or the deposition rate increased) in situ so that the net deposition rate increases. In the preferred embodiment, etch rate is reduced by reducing the bias level provided by RF generator 108 shown in FIG. 1.

When the concurrent etch is reduced or eliminated, the deposition of interlayer dielectric 20-202 becomes more conformal. That is to say, that the growth rate or deposit rate on the sidewalls becomes close to the deposition rate at the base of the gap. Although such deposition conditions are unacceptable for the initial high aspect ratio structure, it can be seen from a comparison of FIG. 2c with FIG. 2a that as the initial phase progresses, the aspect ratio of the remaining gap decreases significantly.

The high conformality deposition continues in the second stage as the gap fills as indicated in FIG. 2d. Interlayer dielectric 202 provides a seam free, void free complete fill of the gap as shown in FIG. 2d.

The etch rate can be reduced in a single step, or in multiple steps as the gap fills and layer 202 increases in thickness. Alternatively, the etch back ratio or the etch back rate can be reduced continuously beginning either at the beginning of the process, or at some point when the ILD layer 202 has reached a predetermined thickness inside the well. These and similar variations of the basic teaching of the method and apparatus of the present invention are considered equivalents to preferred embodiments described herein.

Methods of reducing the etch rate are well known, and include altering the bias on wafer 102 (shown in FIG. 1) by controlling RF generator 108. By reducing the bias on wafer 102, ions in the plasma are not accelerated with as much energy towards the surface of wafer 102 and hence sputtering is reduced. Alternatively or in addition, the partial pressure of the inert gas inside reaction chamber 101 can be reduced using flow controller 114. Reducing the partial pressure of the inert gas in the plasma results in fewer inert gas atoms having sufficient energy to sputter material from ILD layer 202 hence reducing the etch rate. Although methods of reducing etch rate are known, incorporation of these methods into a multi-step or continuously variable concurrent etch/deposit process are heretofore unknown.

By now it should be appreciated that an improved method for deposition of interlayer dielectrics having a high deposition rate is provided. While the specific embodiment involves deposition of an interlayer dielectric between patterned features of a patterned metal layer, it will be apparent that the teachings of the present invention can be applied to other structures and CVD depositions processes used in integrated circuit manufacturing. The preferred embodiment uses an oxide deposition, but its teachings are applicable to concurrent etch/deposit systems for other materials, including silicon nitride, metals, and semiconductor layers. While the preferred embodiment uses plasma etching as the variable etch rate feature, other etch systems are known including chemical etching. These and other alternatives are equivalent to the apparatus and method described herein and are within the scope and sprit of the present invention and claims.

We claim:

1. A chemical vapor deposition (CVD) process comprising the steps of:
providing a plasma reactor;
providing a substrate in the plasma reactor;
supplying process gases including a reactant species and etchant to the upper surface of substrate;
creating a plasma near the upper surface of the substrate so as to simultaneously:
1) deposit a film from the reactant species at a deposition rate D, and
2) etch the deposited film at a rate E, wherein a ratio D:E defines a net deposition rate; and
varying the net deposition rate at least one time during the deposition.

2. The method of claim 1 wherein the net deposition rate is continuously varied during the deposition.

3. The method of claim 1 wherein the net deposition rate is increased during the deposition.

4. The method of claim 1 wherein the net deposition rate is varied by decreasing the substrate bias to decrease the etch rate.

5. The method of claim 1 wherein the net deposition is varied by decreasing a partial pressure of the etchant in the reaction chamber thereby decreasing the etch rate.

6. The method of claim 1 wherein the etchant comprises a neutral species and the step of etching is performed by sputter etching by the plasma activated neutral species.

7. The method of claim 1 wherein the reactant species comprises a compound selected from the group consisting of silane O₂ and TEOS.

8. A process for filling gaps between adjacent patterned features on a semiconductor wafer with an interlayer dielectric, ILD, the process comprising the steps of:
during a first cycle, concurrently depositing and etching the ILD at a first deposit:etch ratio;
during a second cycle, concurrently depositing and etching the ILD at a second deposit:etch ratio wherein the second deposit:etch ratio is greater than the first deposit:etch ratio.

9. An apparatus for filling a gap between adjacent patterned metal features on a semiconductor substrate with an interlayer dielectric (ILD), the method comprising the steps of:
a plasma reactor;
a semiconductor wafer mounted in the plasma reactor;
a source of process gases including a reactant species;
a source of a neutral species;
a flow controller for varying the partial pressure of the neutral species in the reactor;
a plasma generator coupled to create a plasma of the process gases and neutral species in a region near an upper surface of the wafer;
means for controllably biasing the wafer with respect to the plasma; and
a control circuit for automatically varying means for controllably biasing during the deposition process thereby changing a deposit:etch ratio.

10. A method for making an integrated circuit comprising the steps of:
forming a first conductive pattern over an upper surface of a semiconductor substrate, the conductive pattern defining a gap between features of the conductive pattern, the gap having a bottom surface and sidewall surfaces;
placing the substrate in a plasma reactor on a first electrode, the reactor having a second electrode;
introducing into the reactor inert gas and gas including silicon and oxygen components;
producing an RF field between the first and second electrodes to cause silicon dioxide to deposit on the bottom and sidewall surfaces of the gap;
during the silicon dioxide deposition, causing the inert gas to sputter the silicon dioxide from the sidewall and bottom surfaces; and
during a later stage of the silicon dioxide deposition, reducing the sputter rate to increase a rate at which the silicon dioxide film is deposited.

11. The method of claim 10 wherein the inert gas comprises argon.

12. The method of claim 10 wherein the step of reducing the sputter rate comprises decreasing the partial pressure of the inert gas in the reactor.

13. The method of claim 10 wherein the step of reducing the sputter rate comprises decreasing a bias of the first electrode with respect to the second electrode.

14. The method of claim 10 wherein before the step of reducing begins the silicon dioxide sputters from the bottom surface of the gap faster than it sputters from the sidewall surfaces of the gap.

15. The method of claim 10 wherein the gap has an initial aspect ratio before the step of reducing the sputter rate begins the aspect ratio decreases to an intermediate aspect ratio.

16. The method of claim 15 wherein the step of reducing the sputter rate begins when the gap reaches the intermediate aspect ratio.

17. The method of claim 10 wherein the step of reducing is performed a plurality of times before the gap is completely filled with silicon dioxide.
